(19) United States
(12) Patent Application Publication
(10) Pub. No.: US 2008/0120451 A1
(43) Pub. Date: May 22, 2008

(54) METHOD AND APPARATUS FOR AUTOMATICALLY ENABLING REPLACEMENT HARDWARE

(76) Inventors: Randolph S. Kolvick, Durham, NC (US); Patrick M. Bland, Raleigh, NC (US)

Correspondence Address: HOFFMAN WARNICK & DALESSANDRO LLC, 75 STATE ST, 14TH FLOOR, ALBANY, NY, 12207, US

(21) Appl. No.: 11/560,422

(22) Filed: Nov. 16, 2006

(51) Int. Cl. H05K 7/10

(52) U.S. Cl. 710/301

(57) ABSTRACT

The invention is directed to a method and apparatus for automatically enabling replacement hardware. A method for automatically enabling hardware in accordance with an embodiment of the present invention includes: setting a presence bit of the hardware to a first value in response to a removal of the hardware from a socket; replacing the hardware into the socket; storing the first value of the presence bit in a memory; and automatically re-enabling the socket based on the stored first value of the presence bit for the socket or for assemblies containing the socket.

### BACKGROUND OF THE INVENTION

1. Field of the Invention

The present invention generally relates to computer hardware. More specifically, the present invention is directed to a method and apparatus for automatically enabling replacement hardware.

2. Related Art

When a computer system (e.g., a server) detects an uncorrectable error in hardware such as a central processing unit (CPU), memory dual in-line memory module (DIMM), adapter, node, etc., the computer system typically reboots with the bad hardware disabled (e.g., by the system firmware) so that the error will not occur again. After the bad hardware is repaired and/or replaced, the new hardware must be re-enabled by a manual command to the system firmware to bring the hardware back on-line. This is required because the system firmware does not automatically recognize the hardware replacement and is unable to automatically re-enable the hardware. Unfortunately, this process can be very time consuming, often requiring a user to locate and view documentation, search through a multitude of firmware menus, and/or contact the hardware vendor.

Accordingly, there is a need for a method and apparatus for automatically enabling replacement hardware.

### SUMMARY OF THE INVENTION

The present invention is directed to a method and apparatus for automatically enabling replacement hardware. In particular, in one embodiment, the present invention automatically detects the replacement of hardware and reports back to system firmware, which automatically enables the new hardware. This is non-trivial because the system may be powered down with AC removed, and the hardware is physically removed during the replacement process. Each piece of hardware is provided with a power source such as a capacitor or battery. When hardware is removed from a socket, a presence bit of the hardware is pulled up to a “1” value by the power source. In a first case, after a repair has been completed (e.g., a component of the hardware is replaced) and the hardware has been re-inserted back into the socket, the “1” value of the presence bit indicates to the system firmware to re-enable the socket on the next system reboot. In a second case, new hardware is provided and inserted back into the socket. The new hardware has a default presence bit value of “1,” which indicates to the system firmware to re-enable the socket on the next system reboot. The system firmware includes a non-volatile memory (e.g., EEPROM) which contains the socket states for reboot.

A first aspect of the present invention is directed to a method for automatically enabling hardware, comprising: setting a presence bit of the hardware to a first value in response to a removal of the hardware from a socket; replacing the hardware into the socket; storing the first value of the presence bit in a memory; and automatically re-enabling the socket based on the stored first value of the presence bit for the socket or for assemblies containing the socket.

A second aspect of the present invention is directed to a system for automatically enabling hardware, comprising: a system for setting a presence bit of the hardware to a first value in response to a removal of the hardware from a socket; a system for storing the first value of the presence bit in a memory in response to a replacement of the hardware into the socket; and a system for automatically resetting the socket based on the stored first value of the presence bit.

The illustrative aspects of the present invention are designed to solve the problems herein described and other problems not discussed.

### BRIEF DESCRIPTION OF THE DRAWINGS

These and other features of this invention will be more readily understood from the following detailed description of the various aspects of the invention taken in conjunction with the accompanying drawings.

FIG. 1 depicts an illustrative system for automatically enabling replacement hardware in accordance with an embodiment of the present invention.

The drawings are merely schematic representations, not intended to portray specific parameters of the invention. The drawings are intended to depict only typical embodiments of the invention, and therefore should not be considered as limiting the scope of the invention. In the drawings, like numbering represents like elements.

### DETAILED DESCRIPTION OF THE INVENTION

As described above, the present invention is directed to a method and apparatus for automatically enabling replacement hardware. In particular, in one embodiment, the present invention automatically detects the replacement of hardware and reports back to system firmware, which automatically enables the new hardware. This is non-trivial because the system may be powered down with AC removed, and the hardware is physically removed during the replacement process. Each piece of hardware is provided with a power source such as a capacitor or battery. When hardware is removed from a socket, a presence bit of the hardware is pulled up to a “1” value by the power source. In a first case, after a repair has been completed (e.g., a component of the hardware is replaced) and the hardware has been re-inserted back into the socket, the “1” value of the presence bit indicates to the system firmware to re-enable the socket on the next system reboot. In a second case, new hardware is provided and inserted back into the socket. The new hardware has a default presence bit value of “1,” which indicates to the system firmware to re-enable the socket on the next system reboot. The system firmware includes a non-volatile memory (e.g., EEPROM) which contains the socket states for reboot.

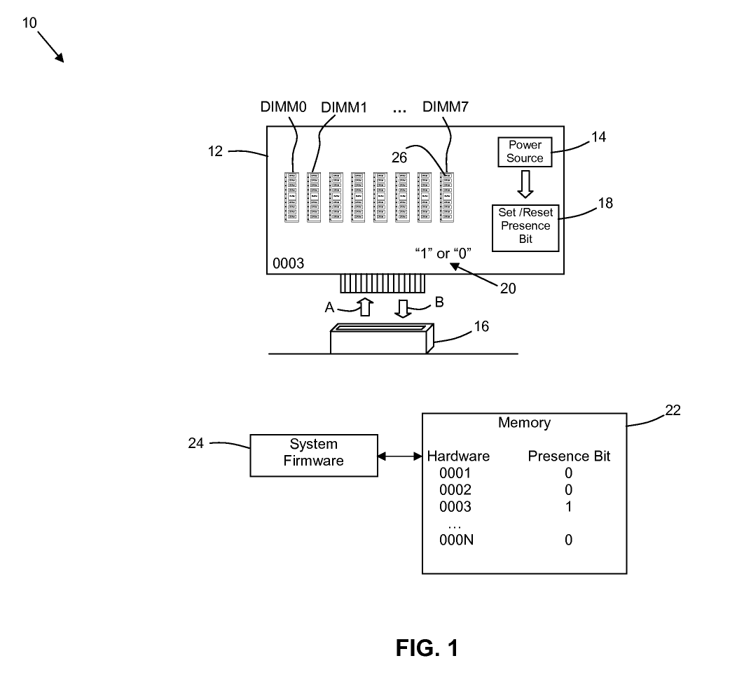

An illustrative system 10 for automatically enabling replacement hardware in a computer system in accordance with an embodiment of the present invention is depicted in FIG. 1. In this example, hardware comprising a memory card 12 including eight DIMMs DIMM 0-DIMM 7 is shown. Other hardware of the computer system that can be automatically enabled in accordance with the present invention is not shown for clarity.

The memory card 12 includes a power source 14 such as a capacitor or battery. When the memory card 12 is removed (arrow A) from a socket 16 in the computer system and a DIMM (e.g., DIMM 7) is removed from the memory card 12, a set/reset system 18 uses the power source 14 to pull the presence bit 20 of the removed DIMM (i.e., DIMM 7) up to a “1” value.

When the memory card 12 is subsequently replaced (arrow B) into the socket 16, for example, after the removed DIMM (i.e., DIMM 7) has been replaced on the memory card 12, after the entire memory card 12 has been replaced, etc., the value of the presence bit 20 of the replacement DIMM (i.e., DIMM 7) is accessed and stored in a memory 22 (e.g., an EEPROM). This can be done, for example, by the system firmware 24 or in any other suitable manner. To this extent, the memory 22 contains socket states for reboot. In this embodiment, the presence bit 20 has a default value of “0” in the memory 22.

As depicted in FIG. 1, the memory 22 is configured to store the value of the presence bit 20 for a plurality of hardware. In this example, the memory card 12 is identified in the memory 22 by the value “0003” and has a corresponding presence bit 20 value of “1.” In accordance with an embodiment of the present invention, the value of the presence bit 20 indicates the following:
“0”=Do not change socket 26 state; and
“1”=Re-enable socket 26.
   The presence bit 20 will have a value of “1” if the memory card 12 has been removed from the socket 16 and a DIMM (e.g., DIMM 7) has been removed from memory card 12 or if the power source 14 has fully discharged. Thus, on reboot, a presence bit 20 value of “1” would indicate to the system firmware 24 to re-enable the socket 26 of the replacement DIMM (i.e., DIMM 7) if currently disabled.

An example of the operation of the present invention is provided below for two cases:
1) DIMM 7 is defective and has been replaced on the memory card 12; and
2) DIMM 7 is defective and the entire memory card 12 is replaced with a new memory card 12 having new DIMMs.

Case (1)—DIMM 7 is defective. A user removes the memory card 12 from the socket 16 and removes DIMM 7 from its socket 26 on the memory card 12. In response, the set/reset system 18 uses the power source 14 to pull the presence bit 20 of DIMM 7 up to a “1” value. After replacing defective DIMM 7 by inserting a replacement DIMM 7 in socket 26 and replacing the memory card 12 into the socket 16, the “1” value of the presence bit 20 is accessed and stored in the memory 22. Upon a subsequent system reboot, the system firmware 24, based on the “1” value of the presence bit 20 associated with DIMM 7, re-enables the socket 26 and resets the presence bit 20 to a “0” value.

Case (2)—DIMM 7 is defective. A user removes the memory card 12 from the socket 16. The memory card 12 is replaced with a new memory card 12 having new DIMMs (including a new DIMM 7). The default value of the presence bit 20 of the new DIMM 7 on the new memory card 12 is “1.” After replacing the new memory card 12, the “1” value of the presence bit 20 is accessed and stored in the memory 22. Upon a subsequent system reboot, the system firmware 24, based on the “1” value of the presence bit 20 associated with DIMM 7, re-enables the socket 26 and resets the presence bit 20 value to a “0” value.

A design tradeoff of the present invention is whether to re-enable sockets in response to the insertion of new hardware or only if the repair is completed in time (where default power up state is do not change socket state after the power source discharges). The example given will cause sockets to re-enable if power is removed for a long period of time. Either approach can be used by a designer. The designer may also decide to automatically re-enable all downstream sockets such as socket 26 of DIMM 7 whenever its higher level assembly such as memory card 12 is removed.

The present invention can also be used to detect part replacement for service or inventory.

At least some aspects of the present invention can be provided on a computer-readable medium that includes computer program code for carrying out and/or implementing the various process steps of the present invention, when loaded and executed in a computer system. It is understood that the term “computer-readable medium” comprises one or more of any type of physical embodiment of the computer program code. For example, the computer-readable medium can comprise computer program code embodied on one or more portable storage articles of manufacture, on one or more data storage portions of a computer system, such as memory and/or a storage system, and/or as a data signal traveling over a network (e.g., during a wired/wireless electronic distribution of the computer program code).

The foregoing description of the embodiments of this invention has been presented for purposes of illustration and description. It is not intended to be exhaustive or to limit the invention to the precise form disclosed, and many modifications and variations are possible.

What is claimed is:

1. A method for automatically enabling hardware, comprising:
setting a presence bit of the hardware to a first value in response to a removal of the hardware from a socket;
replacing the hardware into the socket;
storing the first value of the presence bit in a memory; and
automatically re-enabling the socket based on the stored first value of the presence bit for the socket or for assemblies containing the socket.

2. The method of claim 1, further comprising:
replacing a component of the hardware prior to replacing the hardware into the socket.

3. The method of claim 1, further comprising:
replacing the hardware in its entirety prior to replacing the hardware into the socket.

4. The method of claim 3, wherein the presence bit value of the replacement hardware is set to the first value by default.

5. The method of claim 1, wherein system firmware accesses the memory and automatically resets the socket based on the stored first value of the presence bit of the hardware.

6. The method of claim 1, wherein a power source on the hardware is used to set the presence bit of the hardware to the first value in response to a removal of the hardware from the socket.

7. The method of claim 1, wherein the presence bit is set to a second value until the hardware is removed from the socket.

8. The method of claim 7, further comprising:
storing the second value of the presence bit in the memory; and
not resetting the socket based on the stored second value of the presence bit.

9. A system for automatically enabling hardware, comprising:
a system for setting a presence bit of the hardware to a first value in response to a removal of the hardware from a socket;
a system for storing the first value of the presence bit in a memory in response to a replacement of the hardware into the socket; and
a system for automatically resetting the socket based on the stored first value of the presence bit.

10. The system of claim 9, wherein the system for automatically resetting comprises system firmware, and wherein the system firmware accesses the memory and automatically resets the socket based on the stored first value of the presence bit of the hardware.

11. The system of claim 9, further comprising:
a power source on the hardware for setting the presence bit of the hardware to the first value in response to a removal of the hardware from the socket.

12. The system of claim 11, wherein the power source is selected from the group consisting of a capacitor and a batter.
